(19) United States
(12) Patent Application Publication
(10) Pub. No.: US 2012/0017966 A1
(43) Pub. Date: Jan. 26, 2012

(54) SOLAR POWER GENERATION SYSTEM WITH CONE -SHAPED PROTRUSIONS ARRAY

(75) Inventors: Jia-Ming Shyu, Changhua City (TW); Sheah-Yh Lee, Changhua City (TW)

(73) Assignee: CHIENKUO TECHNOLOGY UNIVERSITY, Changhua City (TW)

(21) Appl. No.: 12/843,493

(22) Filed: Jul. 26, 2010

(51) Int. Cl. H01L 31/042

(52) U.S. Cl. 136/244

(57) ABSTRACT

A solar power generation system includes multiple cones connected to a base in an array fashion and each cone includes multiple solar panels connected to the boards thereof so that the incoming light is fully absorbed and most of the spectrum of light energy will convert into electric energy by the different solar panels on any board of the cones. The cone-shaped array solar power generation system includes larger absorbing area to absorb light from different angles and the efficiency of photoelectric conversion of the solar power generation system increases. The cone-shaped array increases mechanical strength of the solar panels, and is easily to be cleaned up and also lowers the temperature of the solar panels.

### FIELD OF THE INVENTION

The present invention relates to a solar power generation system, and more particularly, to a photovoltaic system which utilizes black body radiation effect, and does not need to coat an anti-reflection layer on the solar panel and the solar tracking system. The solar power generation system absorbs full spectrum of the full incoming sunlight and transfers the sunlight into electric energy via different solar panels on the surfaces of the cone-shaped protrusions. The system has reinforced mechanical strength and better heat dispensing feature. The protrusions are able to be installed on an object with irregular surface.

### BACKGROUND OF THE INVENTION

Due to increasing demand for new energy to meet requirements of the modern living way, the energy from the earth is gradually exhausted and a new replacement energy source is needed. The solar energy is one of the replacement energy which is a battery made of semi-conductive material and the solar battery transforms light energy into electric energy.

The conventional solar power generation system includes a flat panel with multiple solar cells composing of an antireflective coating, a first conductive layer or contact grid, a photoelectric conversion layer and a second conductive layer or back contact on a base board made of glass or silicon, an antireflective layer and a lead wire. The incoming light reaches the base board from the bottom thereof and is reflected, the light passes through the first conductive layer and reaches the photoelectric conversion layer which generates electron flows and electron hole flows. The light passes through the first and second conductive layers and is sent to outside of the base board. However, there is a flat surface located between the first conductive layer and the photoelectric conversion layer, before the incoming light is reflected into the photoelectric conversion layer, a part of the incoming light is reflected and scattered by the flat surface between the first conductive layer and the photoelectric conversion layer, and moves away from the photoelectric conversion layer, so that this part of the incoming light is not absorbed by the photoelectric conversion layer and the efficiency of the solar cells are reduced. Therefore, some developers put an anti-reflection layer on the surface of the solar panel, but this will increase the cost and time required for manufacturing the solar panels. Due to different material characteristics, energy saved can transfer partial spectrum or light into power.

Furthermore, the sunlight energy which is not transferred into energy in the solar cells escapes from the photovoltaic cells by way of reflection or it becomes thermal energy which is trapped in the solar cells to cause overheat to the parts of the PV cells. The phenomenon of overheat reduces the conversion efficiency of the solar cells. Generally, the solar cells dispense the heat by two ways, one of which is that the heat is sent to outside air by way of radiation via the package surface of the solar cells. The other way is to deliver the heat to another circuit board by the package structure and the circuit board sending the heat to the outside air. However, when the solar energy absorbed by the solar cells is doubled, the temperature increases dramatically and the heat cannot be quickly escaped from the package surface of the circuit board to the outside air. Therefore, the efficiency of photoelectric conversion reduces.

Besides, the base board of the solar panel is a hard board and occupies certain space, it cannot be mounted to an irregular surface so that restriction of use is a problem and is one of the main concerns of the conventional solar power generation. In addition, in order to let the solar panel to constantly aim the sun to increase the absorbed sunlight and the generated power, some power generation systems are equipped with sun tracking system. Nevertheless, the sun tracking system increases the cost due to maintenance and consums of electric power.

The present invention intends to provide a solar power generation system which is designed to improve the shortcomings of the conventional solar panels.

### SUMMARY OF THE INVENTION

The main object of the present invention is to provide a solar power generation system which comprises multiple cones connected to a base in an array fashion and the adjacent surfaces between the cones with solar panels made by different materials. The solar panels on the boards of the cones can be any materials with different spectrum absorbing capabilities as mentioned above. When the incoming light reaches the boards of the cones, the light reflects, diffuses and is absorbed, just like entering a black hole and won't be released. Any angular board of the cones can absorb the reflected light of the same or different spectrums so as to increase the effective areas for absorbing the light. That means that the light energy can be effectively collected and the solar panels transfer the solar energy into electric energy, which is used to generate electric power.

Another object of the present invention is to provide a solar power generation system wherein air flows through the gaps between the cones to increase the convection heat transfer, so that the heat dispensing area increases; as the heat is dispensed quickly and the efficiency of the photovoltaic conversion will increase.

A further object of the present invention is to provide a solar power generation system wherein the base of the solar panels are flexible, so that the solar power generation system can be applied to irregular surfaces of objects.

Yet another object of the present invention is to provide a solar power generation system wherein the manufacturing cost becomes low and there is no need to add anti-reflection layer as long as the angles of the cones are small and no incoming sunlight will escape from the array. And there will be no need to install the sun tracking system so as to reduce the time required and the cost for manufacturing.

The solar power generation system of the present invention comprises multiple cones connected to a base in an array manner and each cone comprises at least three boards. Each cone has a bottom surface which can be right triangle surface, square surface, rhombic surface, rectangular surface or hexagonal surface.

Multiple solar panels made of different materials are connected to the corresponding boards of the cones and the solar panels on the cones, which may have any material mentioned above. The solar panels transfer the solar energy from full spectrum of light into electric energy which is used to generate electric power.

The present invention will become more obvious from the following description as in connection with the accompanying drawings, for purposes of illustration only, a preferred embodiment in accordance with the present invention.

### BRIEF DESCRIPTION OF THE DRAWINGS

FIG. 1 is a perspective view to show the solar power generation system of the present invention;

FIG. 2 is a side cross sectional view of the solar power generation system of the present invention;

FIG. 3 is a side view of the second embodiment of the solar power generation system of the present invention;

FIG. 4 is a side cross sectional view of the third embodiment of the solar power generation system of the present invention, and

FIG. 5 is a top view of the arrowed cones and the cones contain triangle bottom surfaces;

FIG. 6 is a top view of the arrowed cones and the cones contain square bottom surfaces, and

FIG. 7 is a top view of the arrowed cones and the cones contain rhombic bottom surfaces.

### DETAILED DESCRIPTION OF THE PREFERRED EMBODIMENT

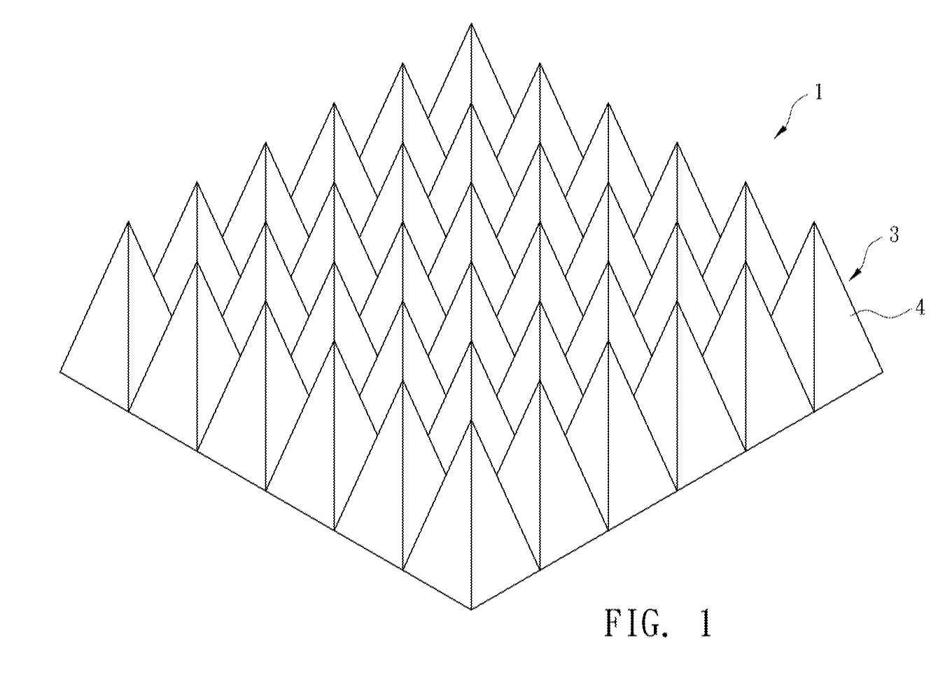

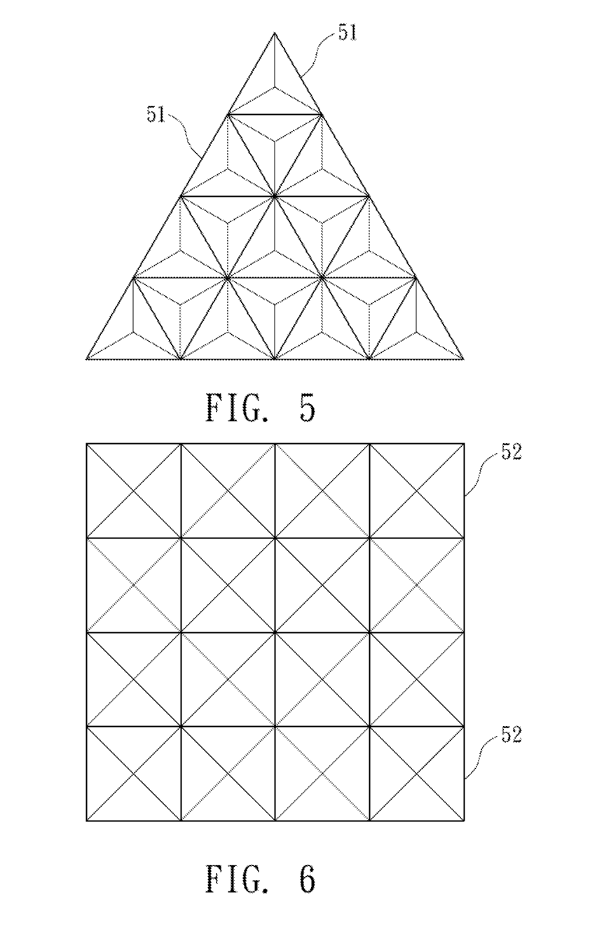

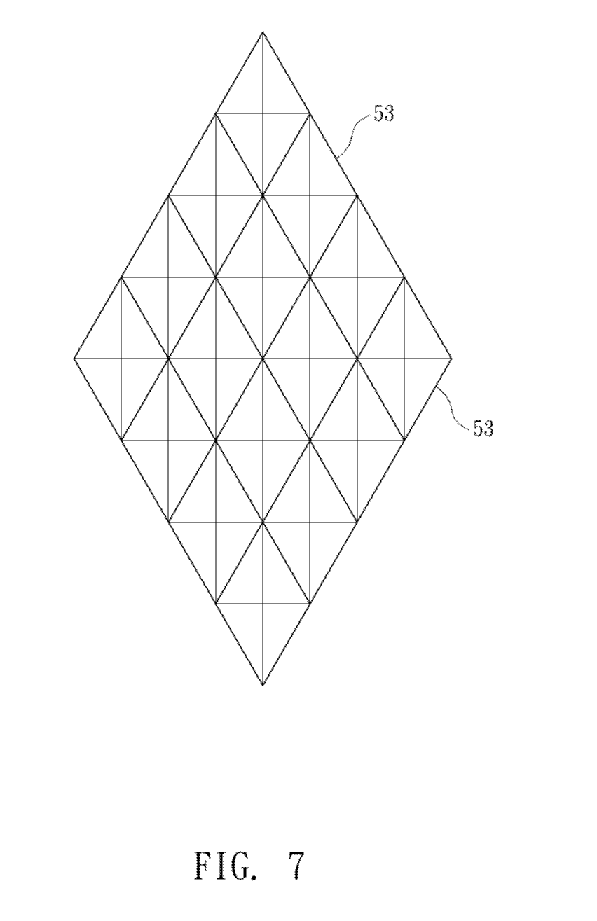

Referring to FIGS. 1 to 5, the solar power generation system 1 of the present invention comprising multiple cones 3 which are connected to a base 2 in an array fashion and each cone 3 comprises at least three boards 31. The bottom surface of each of the cones 3 can be a triangle bottom surface, a quadrilaterals bottom surface or a hexagonal bottom surface, wherein the quadrilaterals includes square, rhombus and rectangle as shown in FIGS. 5 and 5. In this embodiment, the bottom surface of the cones can be a right triangle surface, a square surface, or a rhombic surface 51, 52, 53. In this embodiment, the bottom surface of the cones 3 is a square bottom surface which is adhered on a top surface of the base 2 by adherent 21 and the base 2 is flexible or hard and inflexible.

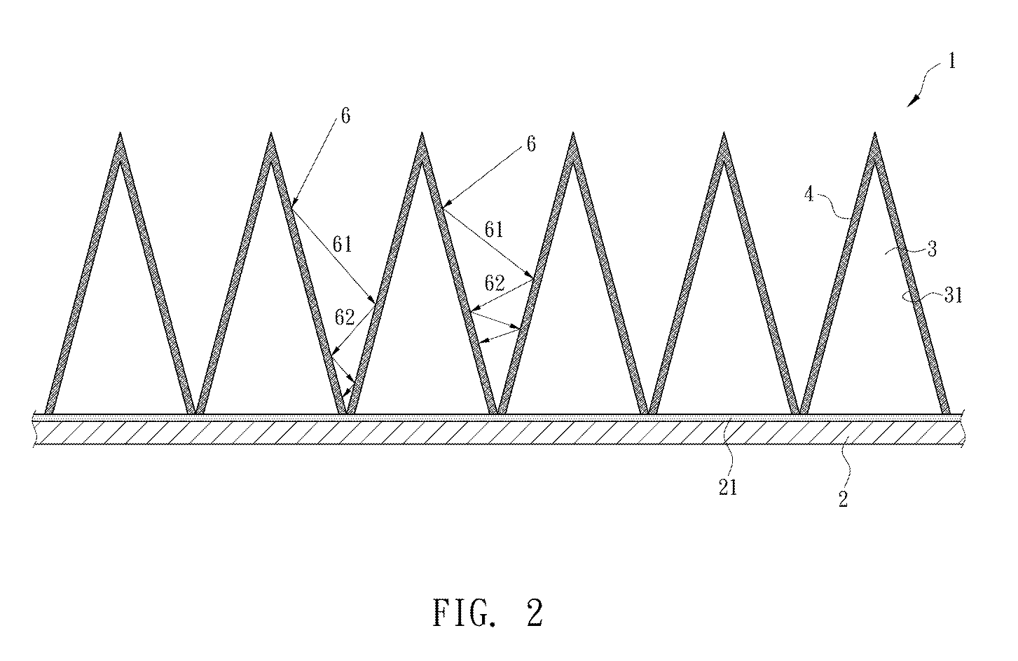

Each board 31 has multiple solar panels 4 connected thereto and each of the solar panels 4 comprises a first conductive layer, a photoelectric conversion layer and a second conductive layer (not shown). As shown in FIG. 2, due to the array arrangement of the cones 3, the incoming light 6 is absorbed with some spectrum of light energy and converted into electric energy and the rest spectrum is reflected by the boards 31 of the cones 3, and forms the first reflected light beam 61 which reaches one of the boards 31 on another cone 3 and also is absorbed with some part of spectrum, and then reflected to another boards 31 to form the second reflected light beam 62. Therefore, the continuous reflection and absorbing to make the light collected effectively and reaching the photoelectric conversion layer via the first and second conductive layers to convert the light into electric energy used to generate electric power.

Besides, each of the solar panels 4 is made of silicon or non-silicon material. The silicon materials include single crystal silicon, polysilicon and amorphous silicon. In particular use, the solar panels on the cone surface can be any kind of materials as long as they can convert full spectrum of light energy complementarily.

Different materials absorb different wavelengths on spectrum and are arranged alternatively on the cones 3 in this embodiment. When the incoming light is reflected by the boards 31 of the cones 3, the light that cannot be absorbed by some of the cones 3 will reach the boards 31 on other cones 3 and will be absorbed by the boards 31. Therefore, the alternatively arranged cones 3 can absorb a wide rage of wavelengths on spectrum. In other words, the present invention careates better efficiency for collecting light and photoelectric conversion.

Besides, the combination of the solar panels 4 and the cones 3 is to include multiple units of solar panels 4 on a top surface of a huge board and the huge board is cut into multiple boards 31 which are connected to be multiple cones 3. The solar power generation system can also be made by an integral cone 3 to reduce the manufacturing cost.

The solar power generation system 1 comprises multiple cones 3 connected to the base 2 in an array manner and each cone 3 has multiple solar panels 4 connected thereto, or one cone 3 performs as a solar power generation system. The incoming light reaches the boards 31 of the cones and the solar power generation system 1 converts the solar energy into electric energy. The reflected light can reach another board 31 or cone 3, which means the light can be absorbed from any direction or angle such that the area for collecting the light is increased. Any angular board 31 of the cones 3 comprises solar panels made of different materials so as to absorb the light of different spectrums. In another word, not only the area for absorbing the light is increased, the light of different spectrums can also be absorbed. The boards 31 or cones 3 are three-dimensional objects so that the air flow will not be stopped and the area for dispensing heat will be increased. The efficiency of photoelectric conversion will then also be increased. Because the base 2 is flexible and the cones 3 is connected to the base 2, the solar power generation system 1 can be applied to different irregular surfaces and effectively reduces the surface temperature and increases the efficiency of photoelectric conversion. The present invention is manufactured at low cost and is a practical innovation. In addition, the cone-shaped structure increases the mechanical strength of the solar panels which bears ice, snow, rain, wind and sand. The rain can clean the surface of the solar battery panels.

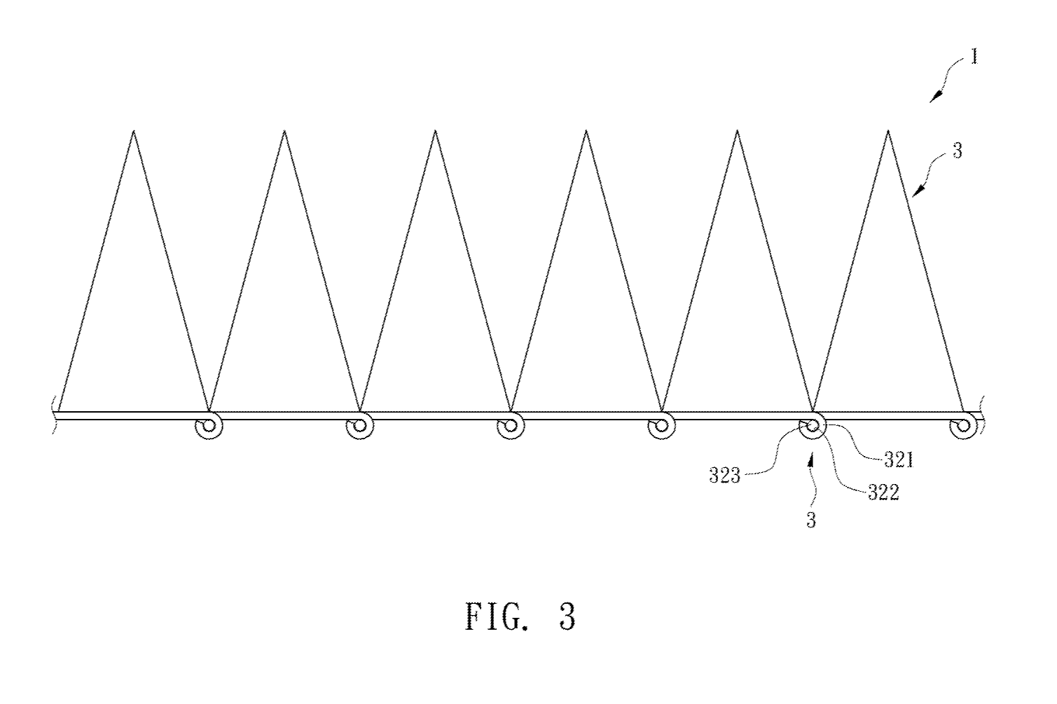

FIG. 3 shows a second embodiment of the present invention, wherein the cones 3 is connected to each other by high sets 32 to form the solar power generation system 1. Each hinge set 32 comprises a hinge member 321 and a pin 323. The hinge member 321 includes a hole 322. Any two adjacent cones 3 respectively contain a hinge member 321 and a pin 323 which extends through the hole 322 and is pivotably connected to the hinge member 321. By this way, the bottom of the solar power generation system 1 is flexible and can be applied on different irregular surfaces.

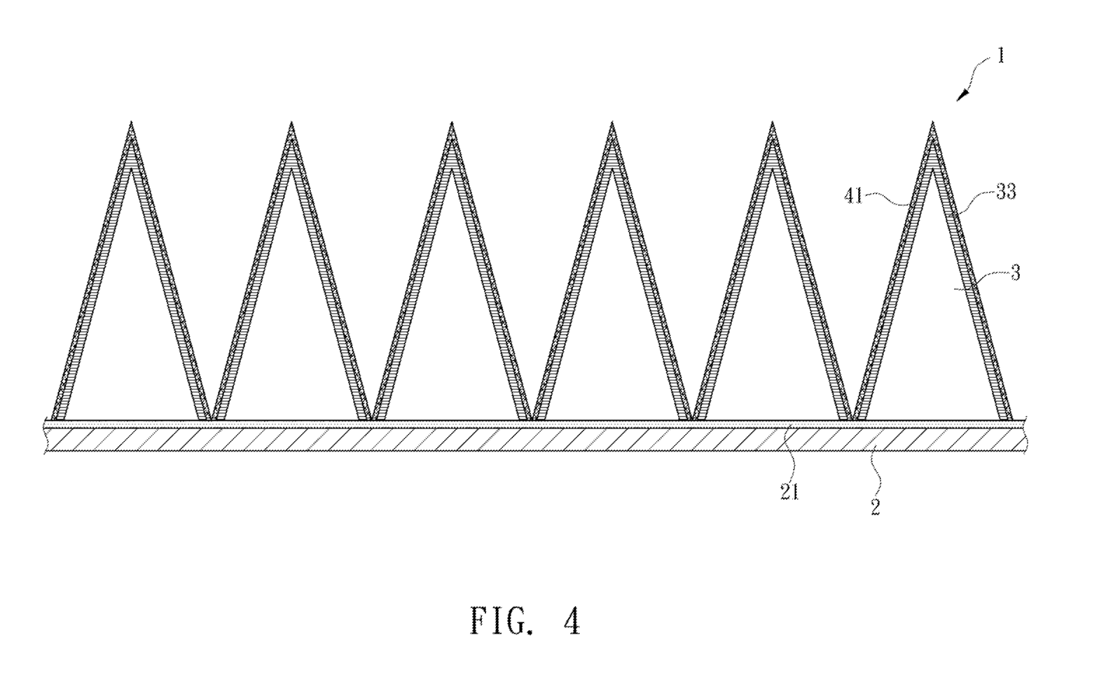

FIG. 4 shows the third embodiment of the present invention, wherein the base 2 includes multiple cones 3 in array form and each cone 3 contains multiple boards 33 or each cone 3 is a single cone-shaped solar power generation system with multiple surfaces. The boards 33 replaces the base of the solar panel and the solar panels 41 is connected to the boards 33 of the cones 3 by way of coating. The solar panels 41 each comprise a first conductive layer, a photoelectric conversion layer and a second conductive layer. The solar panel in this embodiment can be made more quickly and efficient.

The fourth embodiment is not disclosed in the drawings and the conductive layers of the solar panels 4 of the cones 3 output pre-set currents and voltages by way of parallel circuits or serial circuits.

While we have shown and described the embodiment of the present invention, it should be clear to those the state-of-the-art creatation that further embodiments may be made without distracting the scope of the present invention.

What is claimed is:

1. A solar power generation system, comprising:
multiple cones connected to a base in an array manner and each cone comprising at least three boards, the corresponding boards between the cones having multiple solar panels connected thereto which are made of different materials, the solar panels on the boards of the cones being made of any material mentioned above so that the incoming light of full spectrums is converted into electric energy by the solar panels and the angle of the cone is small so that the incoming light with full spectrum does not escape from the array and is converted to electric energy within the array.

2. The solar power generation system as claimed in claim 1, wherein the base of the solar panel is flexible.

3. The solar power generation system as claimed in claim 1, wherein a bottom surface of each of the cones is adhered on a top surface of the base, and the surface of base is flat or flexible.

4. The solar power generation system as claimed in claim 1, wherein each of the solar panels comprises a surface glass protection layer, a first conductive layer, a photoelectric conversion layer, a second conductive layer and a bottom conductive layer.

5. The solar power generation system as claimed in claim 1, wherein boards are cut from a huge board which comprises multiple solar panels connected thereon and each solar panel comprises a first conductive layer, a photoelectric conversion layer and a second conductive layer, the boards form cones.

6. The solar power generation system as claimed in claim 1, wherein the conductive layers of the solar panels of the cones output pre-set currents and voltages by way of parallel circuits or serial circuits.

7. The solar power generation system as claimed in claim 1, wherein the solar panels is connected to the boards of the cones by way of coating.

8. The solar power generation system as claimed in claim 1, wherein the bottom surface of the cones is a triangle bottom surface, a quadrilaterals bottom surface or a hexagonal bottom surface, wherein the quadrilaterals includes square bottom surface, rhombus bottom surface and rectangle triangular bottom surface.

9. The solar power generation system as claimed in claim 1, wherein each of the solar panels is made of silicon, non-silicon, or amorphous material, the solar panels made of different materials absorb different wavelengths on spectrum and arranged alternatively on the cones.

10. The solar power generation system as claimed in claim 1, wherein the silicon materials includes single crystal silicon, polysilicon and amorphous silicon, the amorphous silicon comprises Cadmium Telluride, Indium Gallium Arsenide, and Gallium Arsenide.
